(19) United States
(12) Patent Application Publication
(10) Pub. No.: US 2009/0294868 A1
(43) Pub. Date: Dec. 3, 2009

(54) DRIVE CURRENT ADJUSTMENT FOR TRANSISTORS FORMED IN THE SAME ACTIVE REGION BY LOCALLY INDUCING DIFFERENT LATERAL STRAIN LEVELS IN THE ACTIVE REGION

(76) Inventors: Uwe Griebenow, Markkleeberg (DE); Kai Frohberg, Niederau (DE); Kerstin Ruttloff, Hainichen (DE); Katrin Reiche, Goltzscha (DE)

Correspondence Address: WILLIAMS, MORGAN & AMERSON, 10333 RICHMOND, SUITE 1100, HOUSTON, TX, 77042, US

(21) Appl. No.: 12/424,095

(22) Filed: Apr. 15, 2009

(30) Foreign Application Priority Data
May 30, 2008 (DE) 10 2008 026 132.7

(51) Int. Cl. H01L 27/092; H01L 21/8238

(52) U.S. Cl. 257/369; 438/199; 257/E27.062; 257/E21.632

(57) ABSTRACT

The drive current capability of a pull-down transistor and a pass transistor formed in a common active region may be adjusted on the basis of a strain-inducing mechanism, such as a stressed dielectric material and a stress memorization technique, thereby providing a simplified overall geometric configuration of the active region. Hence, static RAM cells may be formed on the basis of a minimum channel length with a simplified configuration of the active region, thereby avoiding significant yield losses as may be observed in sophisticated devices in which a pronounced variation of the transistor width may be used to adjust the ratio of the drive current capabilities for the pull-down transistor and the pass transistor.

### BACKGROUND OF THE INVENTION

1. Field of the Invention

Generally, the present disclosure relates to integrated circuits, and, more particularly, to the manufacture of field effect transistors in complex circuits including memory areas, for instance in the form of a cache memory of a CPU.

2. Description of the Related Art

Integrated circuits comprise a large number of circuit elements on a given chip area according to a specified circuit layout, wherein transistor elements represent one of the major semiconductor elements in the integrated circuits. Hence, the characteristics of the individual transistors significantly affect overall performance of the complete integrated circuit. Generally, a plurality of process technologies are currently practiced, wherein, for complex circuitry, such as microprocessors, storage chips, ASICs (application specific ICs) and the like, MOS technology is currently one of the most promising approaches due to the superior characteristics in view of operating speed and/or power consumption and/or cost efficiency. During the fabrication of complex integrated circuits using MOS technology, millions of transistors, i.e., N-channel transistors and/or P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the mobility of the majority charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially determines the performance of the MOS transistors. Thus, the latter aspect renders the reduction of the channel length, and associated therewith the reduction of the channel resistivity, a dominant design criterion for accomplishing an increase in the operating speed of the integrated circuits.

On the other hand, the drive current capability of the MOS transistors also depends on the transistor width, i.e., the extension of the transistor in a direction perpendicular to the current flow direction, so that the gate length and thus the channel length, in combination with the transistor width, are dominant geometric parameters, which substantially determine the overall transistor characteristics in combination with “transistor internal” parameters, such as overall charge carrier mobility, threshold voltage, i.e., a voltage at which a conductive channel forms below the gate insulation layer upon applying a control signal to the gate electrode, and the like. On the basis of field effect transistors, such as N-channel transistors and/or P-channel transistors, more complex circuit components may be created, depending on the overall circuit layout. For instance, storage elements in the form of registers and static RAM (random access memory), may represent important components of complex logic circuitries. For example, during the operation of complex CPU cores, a large amount of data has to be temporarily stored and retrieved, wherein the operating speed and the capacity of the storage elements have a significant influence on the overall performance of the CPU. Depending on the memory hierarchy used in a complex integrated circuit, different types of memory elements are used. For instance, registers and static RAM cells are typically used in the CPU core due to their superior access time, while dynamic RAM elements are preferably used as working memory due to the increased bit density compared to registers or static RAM cells. Typically, a dynamic RAM cell comprises a storage capacitor and a single transistor, wherein, however, a complex memory management system is required so as to periodically refresh the charge stored in the storage capacitors which may otherwise be lost due to unavoidable leakage currents. Although the bit density of dynamic RAM devices may be very high, a charge has to be transferred from and to the storage capacitors in combination with periodic refresh pulses, thereby rendering these devices less efficient in terms of speed and power consumption compared to static RAM cells. Thus, static RAM cells may be advantageously used as high speed memory with moderately high power consumption thereby, however, requiring a plurality of transistor elements for the reliable storage of an information bit.

FIG. 1a schematically illustrates a circuit diagram of a static RAM cell 150 in a configuration as may typically be used in modern integrated circuits. The cell 150 comprises a storage element 151, which may include two inversely coupled inverters 152A, 152B, each of which may include a couple of transistors 100A, 100C. For example, in a CMOS device, the transistors 100A, 100C may represent an N-channel transistor and a P-channel transistor, respectively, while, in other cases, transistors of the same conductivity type, such as N-channel transistors, may be used for both the transistors 100A and 100C. A corresponding arrangement of N-channel transistors for the upper transistors 100C is illustrated at the right-hand side of FIG. 1a. Moreover, respective pass transistors 100B may typically be provided to allow a connection to the bit cell 150 for read and write operations, during which the pass transistors 100B may connect the bit cell 150 to corresponding bit lines (not shown), while the gate electrodes of the pass transistors 100B may represent word lines of the memory cell 150. Thus, as illustrated in FIG. 1a, six transistors may be required to store one bit of information, thereby providing a reduced bit density for the benefit of a moderately high operating speed of the memory cell 150, as previously explained. Depending on the overall design strategy, the memory cell 150 may require the various transistor elements 100A, 100B, 100C to have different characteristics with respect to drive current capability in order to provide reliable operational behavior during read and write operations. For example, in many design strategies, the transistor elements are provided with minimum transistor length, wherein the drive current capability of the transistors 100A, which may also be referred to as pull-down transistors, may be selected to be significantly higher compared to the drive current capability of the pass transistors 100B, which may be accomplished by appropriately adjusting the respective transistor width dimensions for the given desired minimum transistor length.

FIG. 1b schematically illustrates a top view of a portion of the memory cell 150 as a hardware configuration in the form of a semiconductor device. As illustrated, the device 150 comprises a silicon-based semiconductor layer 102, in which an active region 103 is defined, for instance, by providing a respective isolation structure 104 that laterally encloses the active region 103, thereby defining the geometric shape and size of the transistors 100A, 100B. As illustrated, the transistors 100A, 100B may be formed in and above the same active region 103 since both transistors may have the same conductivity type and may be connected via a common node, as is, for instance, illustrated as nodes 153A, 153B in FIG. 1a. As previously explained, the transistors 100A, 100B, i.e., the pull-down transistor and the pass transistor, may have substantially the same length so that respective gate electrodes 106 may have substantially the same length 106L, whereas a transistor width 103A of the pull-down transistor 100A may be greater compared to a transistor width 103B of the pass transistor 10B, in order to establish the different current capabilities of these transistors.

FIG. 1c schematically illustrates a cross-sectional view taken along the line 1c of FIG. 1b. As illustrated, the device 150 comprises a substrate 101 which may typically be provided in the form of a silicon substrate, possibly in combination with a buried insulating layer (not shown) if a silicon-on-insulator (SOI) configuration is considered. Above the substrate 101 and a possible buried insulating layer, the semiconductor layer 102 in the form of a silicon layer is provided, in which the isolation structure 104 may be formed according to the desired shape to define the active region 103 according to the configuration as shown in FIG. 1b. That is, the active region 103 has the width 103A in the transistor 100A and has the width 103B in the transistor 100B. In this respect, an active semiconductor region is to be understood as a semiconductor region having an appropriate dopant concentration and profile so as to form one or more transistor elements in and above the active region, which have the same conductivity type. For example, the active region 103 may be provided in the form of a lightly P-doped semiconductor material, for instance in the form of a P-well, when the semiconductor layer 102 may extend down to a depth that is significantly greater than the depth dimension of the transistors 100A, 100B, when the transistors 100A, 100B may represent N-channel transistors. Similarly, the active region 103 may represent a basically N-doped region when the transistors 100A, 100B represent P-channel transistors. Furthermore, in the manufacturing stage shown in FIG. 1c, the transistors 100A, 100B may comprise the gate electrode 106, for instance in the form of a polysilicon material, which is separated from a channel region 109 by a gate insulation layer 108. Furthermore, depending on the overall process strategy, a sidewall spacer structure 107 may be formed on sidewalls of the gate electrodes 106. Additionally, drain and source regions 110 may be formed in the active region 103 and may connect the transistors 100A, 100B. Typically, metal silicide regions 111 are provided in the gate electrode 106 and an upper portion of the drain and source regions 110 to reduce contact resistance of these areas.

The device 150 is typically formed on the basis of the following processes. First, the isolation structure 104 may be formed, for instance as a shallow trench isolation, by etching respective openings into the semiconductor layer 102 down to a specific depth, which may even extend to a buried insulating layer, if provided. Thereafter, the corresponding openings may be filled with an insulating material by deposition and oxidation processes, followed by a planarization such as chemical mechanical polishing (CMP) and the like. During the process sequence for the isolation structure 104, advanced lithography techniques may have to be used in order to form a corresponding etch mask, which substantially corresponds to the shape of the active region 103, which requires the definition of a moderately narrow trench so as to obtain the desired reduced width 103B of the transistor 100B. Thereafter, the basic doping in the active region 103 may be provided by performing respective implantation sequences, which may also include sophisticated implantation techniques for introducing dopants for defining the channel doping and the like. Next, the gate insulation layers 108 and the gate electrodes 106 may be formed by depositing, oxidizing and the like an appropriate material for the gate insulation layer 106, followed by the deposition of an appropriate gate electrode material, such as polysilicon. Subsequently, the material layers are patterned by using advanced lithography and etch techniques, during which the actual length 106L of the gate electrodes 106 may be adjusted, thereby acquiring extremely advanced process techniques to obtain a gate length of approximately 50 nm and less. Next, a part of the drain and source regions 110 may be formed by implanting appropriate dopant species, followed by the formation of the spacer structure 107, or at least a portion thereof, followed by a subsequent implantation process for defining the deep drain and source areas, wherein a corresponding implantation sequence may be repeated on the basis of an additional spacer structure if sophisticated lateral concentration profiles may be required in the drain and source regions 110. Thereafter, appropriate anneal processes may be performed to re-crystallize implantation-induced damage in the active region 103 and also to activate the dopant species in the drain and source areas 110. It should be appreciated that, for a reduced gate length in the above-defined range, the sophisticated geometric configuration of the active region 103 may result in process non-uniformities, for instance during the deposition and etching of a spacer material for forming the sidewall spacer 107. Typically, the spacer structure 107 is formed by depositing an appropriate material, for instance a silicon dioxide liner (not shown), followed by a silicon nitride material, which may subsequently be selectively etched with respect to the silicon dioxide liner on the basis of well-established anisotropic etch recipes. However, at areas indicated as 112 in FIG. 1b, irregularities may be observed which may even be increased due to respective non-uniformities created during previously performed lithography processes, such as the lithography process for patterning the gate electrodes 106 and the like. Consequently, the areas 112 may have a significant influence on the further processing of the device 150, which may finally result in a non-predictable behavior of the transistor 100B and thus the overall memory cell 150. For example, during the further processing, the metal silicide regions 111 may be formed by depositing a refractory metal, such as nickel, cobalt and the like, which may then be treated to react with the underlying silicon material, wherein typically the isolation structure 104 and the spacer structure 107 may substantially suppress the creation of a highly conductive metal silicide. However, due to the previously generated irregularities, respective leakage paths or even short circuits may be created, thereby undesirably influencing the final drive current capability of the transistor 100B, which may result in a less stable and reliable operation of the memory cell 150, thereby significantly contributing to yield loss of sophisticated semiconductor devices including static RAM areas.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to methods and semiconductor devices in which the drive current capability of transistor elements formed in and above the same active region may be adjusted on the basis of different strain levels created in the respective channel regions of the transistors, thereby enabling a simplified overall geometry of the active region, which, in some illustrative embodiments, may even be provided in a substantially rectangular configuration so that a substantially identical transistor width may be obtained for the various transistor elements while nevertheless providing a significant difference in current drive capability. In some illustrative aspects disclosed herein, the adjustment of the drive current capability may be accomplished for transistor elements of a memory cell, thereby obtaining the desired difference in transistor characteristics while providing simplified overall transistor geometry compared to conventional static RAM cells. The adjustment of the drive current capability may be accomplished, in some illustrative aspects, by providing a dielectric material with different internal stress levels above the various transistor elements so as to selectively influence the charge carrier mobility in the corresponding channel regions. In other illustrative aspects, additionally or alternatively, strain levels may be created during the manufacturing process for forming the transistors by applying a selective stress memorization technique, i.e., a technique in which the drain and source regions of one of the transistors may be re-crystallized in a strained state during a corresponding anneal process while another transistor may have a significantly reduced strain level. Hence, also based on a stress memorization technique, possibly in combination with appropriately stressed dielectric materials, an efficient adjustment of a ratio of drive current capabilities of transistors formed in and above the same active region may be accomplished, thereby reducing yield losses, which may typically be observed in static RAM cells of sophisticated semiconductor devices including transistors having a gate length of approximately 50 nm and less.

One illustrative method disclosed herein comprises forming a first transistor of a memory cell above a substrate of a semiconductor device, wherein the first transistor has a first conductivity type and a first transistor width. The method additionally comprises forming a second transistor of the memory cell, wherein the second transistor has the first conductivity type and the first transistor width. Finally, a ratio of drive current capabilities of the first and second transistors is adjusted by inducing different strain levels in channel regions of the first and second transistors.

Another illustrative method disclosed herein comprises forming a first transistor in and above an active semiconductor region and forming a second transistor in and above the active semiconductor region. The method further comprises inducing a first strain level in a channel region of the first transistor and inducing a second strain level in a channel region of the second transistor, wherein the second strain level differs from the first strain level in at least one type of strain and magnitude.

One illustrative semiconductor device disclosed herein comprises an active semiconductor region formed above a substrate and a first transistor formed in and above the active semiconductor region, wherein the first transistor comprises a first channel region having a first strain level. The semiconductor device further comprises a second transistor formed in and above the active semiconductor region, wherein the second transistor comprises a second channel region having a second strain level that differs from the first strain level.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a circuit diagram of a conventional static RAM cell including two inverters and respective pass transistors;

FIG. 1b schematically illustrates a top view of the memory cell of FIG. 1a, wherein a ratio of drive current capabilities is adjusted by providing different widths of the pull-down transistor and the pass transistor, according to conventional techniques;

FIG. 1c schematically illustrates a cross-sectional view of the transistors shown in FIG. 1b, according to conventional techniques;

FIG. 2a schematically illustrates a top view of a portion of an active region, in and above which transistors of the same conductivity type and substantially the same transistor length may be formed so as to have a different drive current capability on the basis of substantially the same transistor width, according to illustrative embodiments;

FIG. 2b schematically illustrates a cross-sectional view of the transistors of FIG. 2a in which different strain levels are provided to adjust the ratio of the drive current capabilities, according to illustrative embodiments;

FIGS. 2c-2f schematically illustrate cross-sectional views of the semiconductor device during various manufacturing stages in inducing different strain levels of the transistors on the basis of dielectric materials having different internal stress levels, according to illustrative embodiments;

FIGS. 2g-2i schematically illustrate top views of the semiconductor device in which various combinations of differently stressed dielectric materials are illustrated, according to further illustrative embodiments;

FIG. 2j schematically illustrates a cross-sectional view of the semiconductor device according to still further illustrative embodiments, in which different strain levels may be accomplished on the basis of a single dielectric material layer, the internal stress level of which may be selectively relaxed; and

FIGS. 3a-3d schematically illustrate cross-sectional views of a semiconductor device during various manufacturing stages in inducing different strain levels of transistor elements formed in and above the same active semiconductor regions on the basis of stress memorization techniques, according to still other illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to methods and semiconductor devices in which the drive current capability of transistor elements formed in the same active region may be selectively adjusted by creating different strain levels locally in the active semiconductor region, wherein, in some illustrative aspects, substantially the same transistor width may be used for the active region, thereby providing a simplified overall geometry which may thus reduce yield losses, for instance, in static memory areas of sophisticated semiconductor devices including transistors of a gate length of approximately 50 nm and less. As is well known, strain in a semiconductor material may significantly affect the charge carrier mobility, which may thus be advantageously used for designing the overall drive current capability of transistors for an otherwise identical transistor configuration. For example, in a silicon-based crystalline active region having a standard crystal configuration, i.e., a (100) surface orientation with a transistor length direction oriented along a <110> crystal axis, the creation of a uniaxial tensile strain component along the transistor length direction may result in a significant increase of electron mobility, thereby enabling the enhancement of drive current capability of N-channel transistors. On the other hand, a uniaxial compressive strain component along the transistor length direction may increase hole mobility and may reduce electron mobility, thereby enabling a reduction of the drive current capability of N-channel transistors. Thus, by locally providing respective strain conditions in the channel regions of the corresponding transistor elements, a significant modulation of the drive current capabilities may be achieved for otherwise similar or substantially identical transistor configurations, for instance with respect to the transistor width and length. Consequently, as previously explained, an overall geometric configuration of an active area with reduced complexity may be used, for instance with respect to static RAM cells, while nevertheless providing efficient strategies for adjusting the ratio of the drive current capabilities while significantly reducing the probability of creating yield losses as may typically be observed in conventional RAM cells including a pronounced variation of the corresponding transistor width dimensions.

A corresponding local strain patterning within a single active semiconductor region, for example for an active region accommodating a pull-down transistor and a pass transistor of a static RAM cell, may be accomplished on the basis of a plurality of strain engineering techniques, such as the provision of a dielectric material including a specific internal stress level. For this purpose, dielectric material that may be positioned close to the basic transistor structure may be used in order to efficiently transfer a respective stress component into the channel region of the transistor, thereby creating the desired type of strain. For example, after completing the basic transistor structure, an interlayer dielectric material is typically formed so as to enclose and passivate the transistors. Typical materials are silicon dioxide in combination with an etch stop material, such as silicon nitride, which may be used for patterning the interlayer dielectric material for receiving contact openings which may subsequently be filled with an appropriate conductive material. The silicon nitride material, which is formed on and above the basic transistor configuration, may be deposited with high internal stress levels of up to 2 GPa and higher of compressive stress and up to 1 GPa and significantly higher of tensile stress by appropriately selecting process parameters during the deposition. That is, the precursor materials, such as silane, ammonia and the like, the pressure thereof, the temperature of the substrate and the like, and in particular the degree of ion bombardment during the deposition may be controlled to obtain the desired type and magnitude of the internal stress level. Consequently, well-established deposition recipes for silicon nitride material, nitrogen-enriched silicon carbide material and the like may be efficiently used to locally pattern the strain level in a single active region in order to adjust the drive current capability of the various transistors formed therein. In other illustrative aspects disclosed herein, in addition to the above-described stress liner approaches or alternatively to these approaches, other strain-inducing mechanisms may be used without substantially unduly contributing to the overall process complexity. For example, stress memorization techniques may be selectively applied to portions of an active region in order to obtain different strain levels for the various transistors formed in and above the corresponding active region. A stress memorization technique is to be understood as a process technique in which a highly damaged crystalline region or a substantially amorphous region may be re-crystallized during an anneal process in the presence of a cap layer, which may have appropriate material characteristics so as to substantially suppress a volume reduction of the re-crystallizing semiconductor material, thereby creating a highly strained state of the re-grown crystal, which may even be preserved after the removal of the cap layer. Thus, upon annealing highly damaged or substantially amorphous drain and source areas of a transistor in the presence of a corresponding cap layer, such as a silicon nitride layer, a strained state of the drain and source regions may be obtained which may be preserved, even after a complete or partial removal of the cap layer, wherein the corresponding strained state may result in a respective tensile strain in the adjacent channel region. Consequently, by selectively applying the stress memorization technique within a single active semiconductor region, an efficient adjustment of drive current capabilities may be accomplished, wherein, in combination with the above-described stress liner approaches, an even further enhanced effect may be obtained. Consequently, in some illustrative embodiments disclosed herein, pull-down transistors and pass transistors of a static RAM cell may be formed in the same active region on the basis of a simplified geometric configuration of the active region compared to conventional approaches, as previously described, while nevertheless creating the desired difference in drive current capability so as to obtain a reliable operation of the memory cell.

It should be appreciated that the principles disclosed herein may be advantageously applied to semiconductor devices including transistor elements having a gate length of 50 nm and less, since, in these cases, pronounced yield losses may be observed for transistor elements formed in an active region having a varying width dimension. However, the present disclosure may also be applied to any device architectures irrespective of the corresponding critical dimensions and hence the present disclosure should not be construed as being restricted to specific transistor dimensions unless such restrictions are specifically set forth in the appended claims.

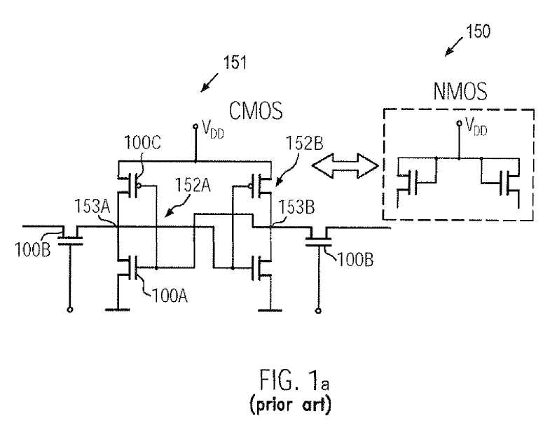

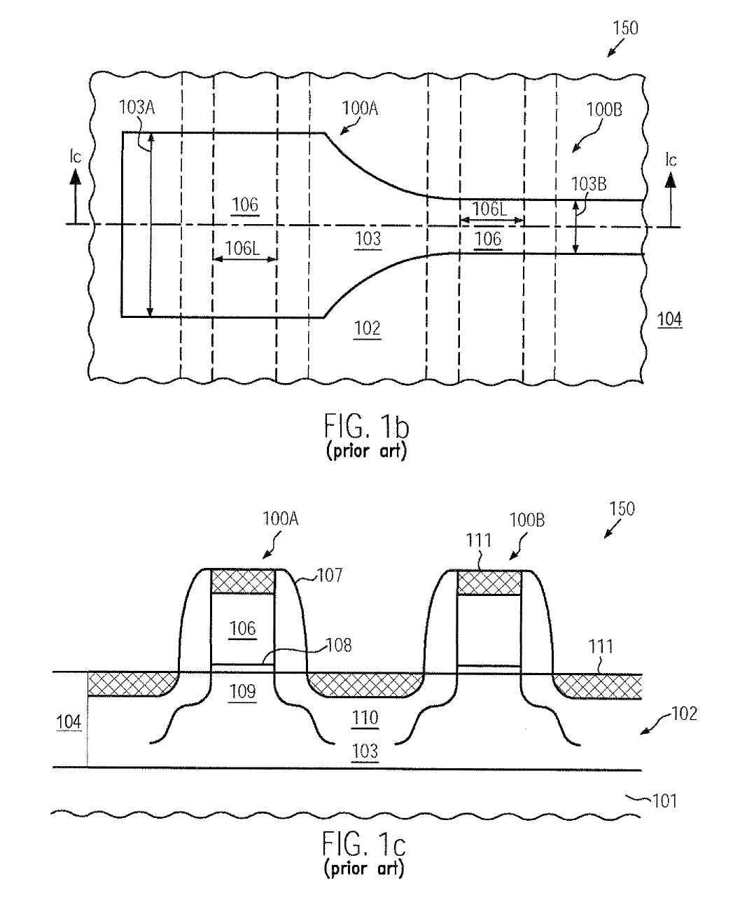

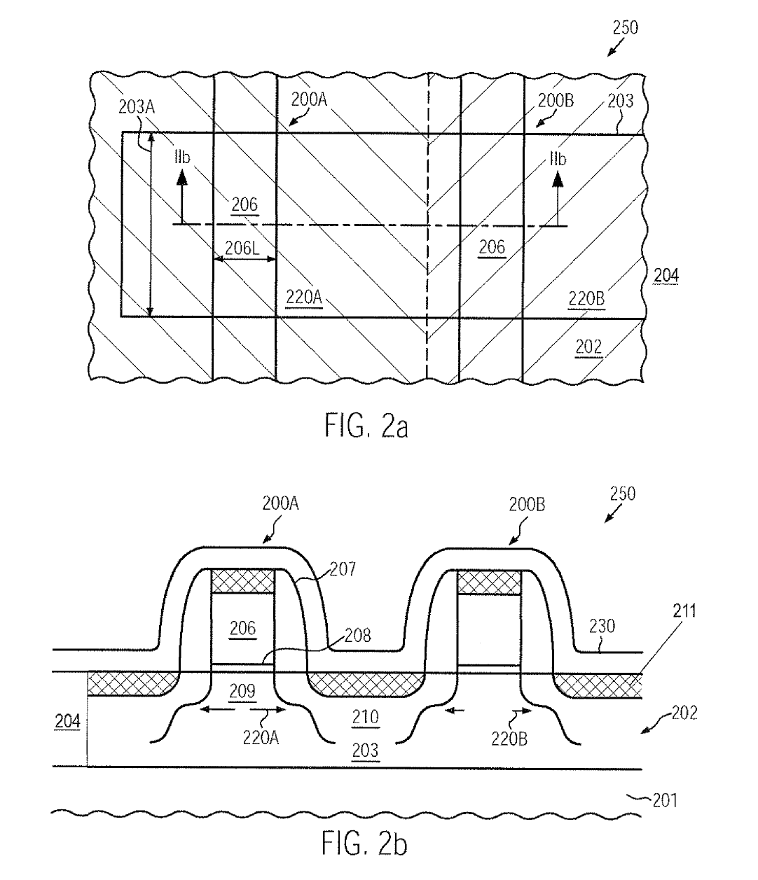

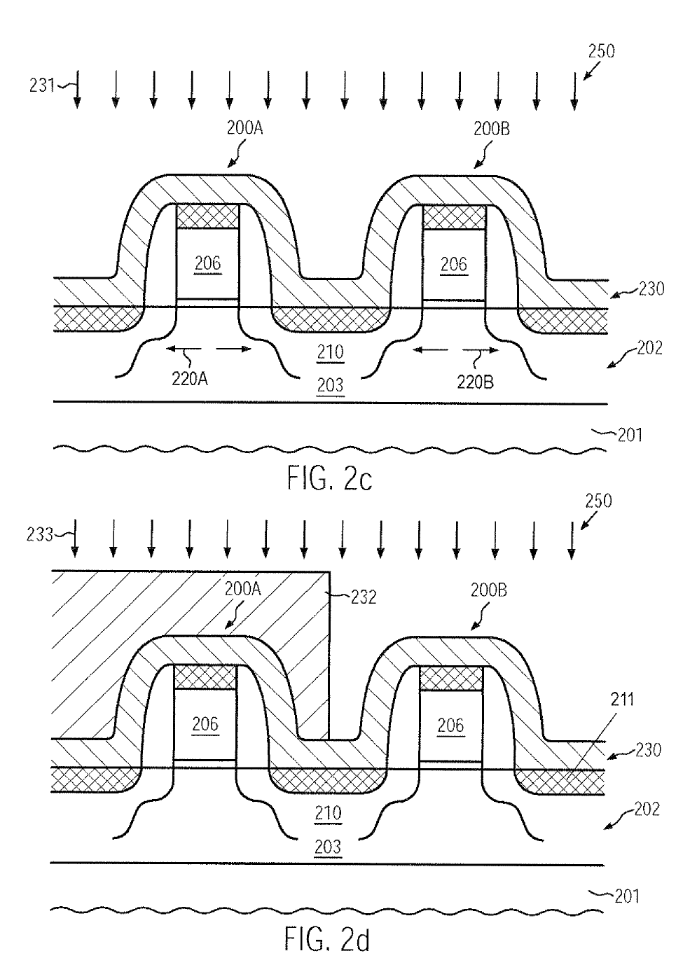

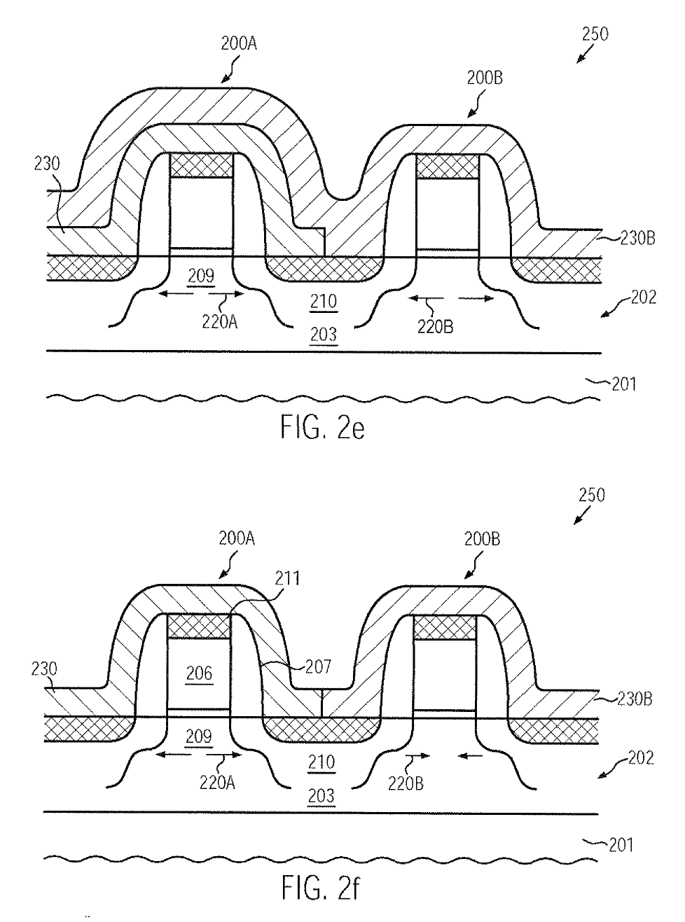

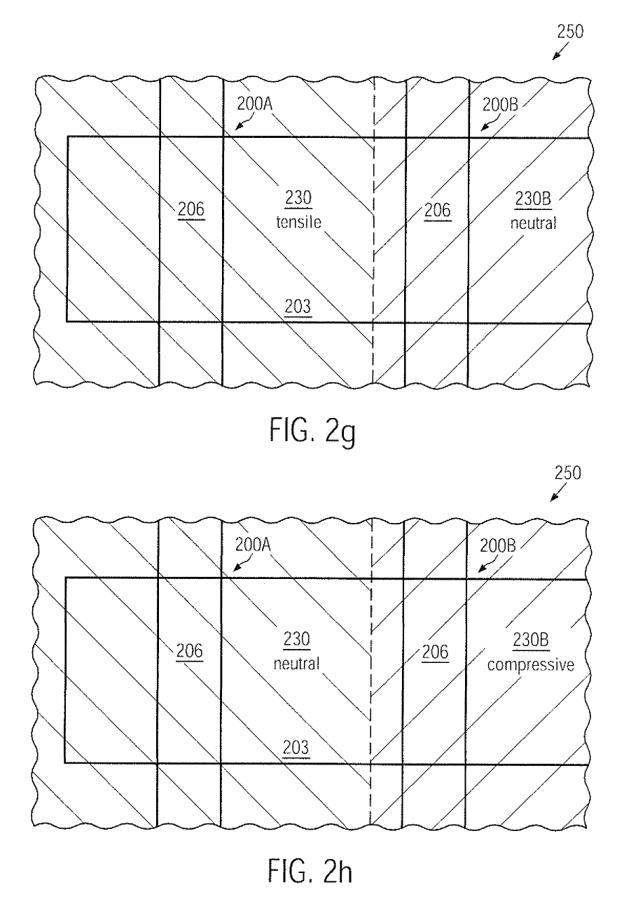

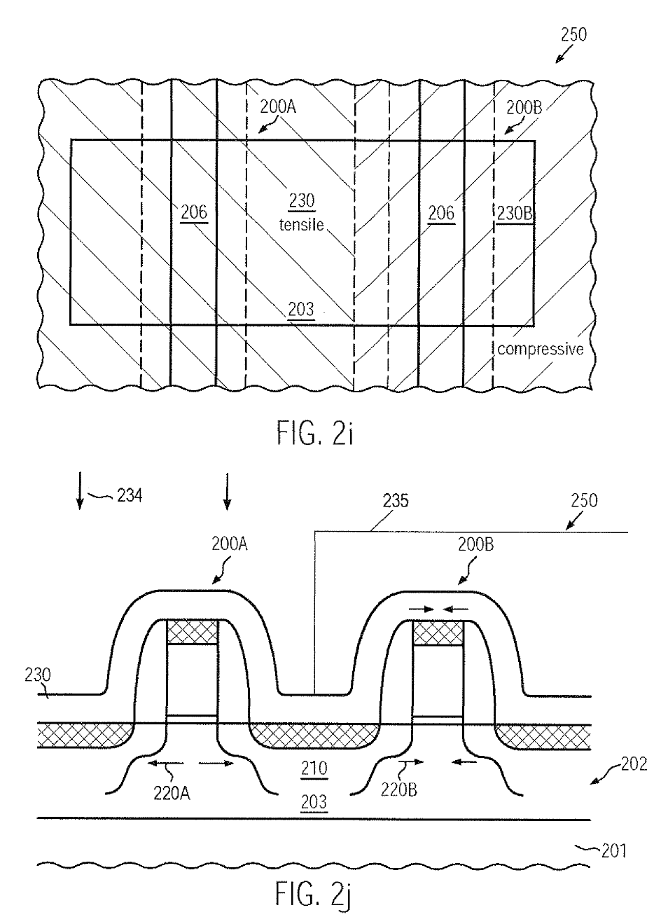

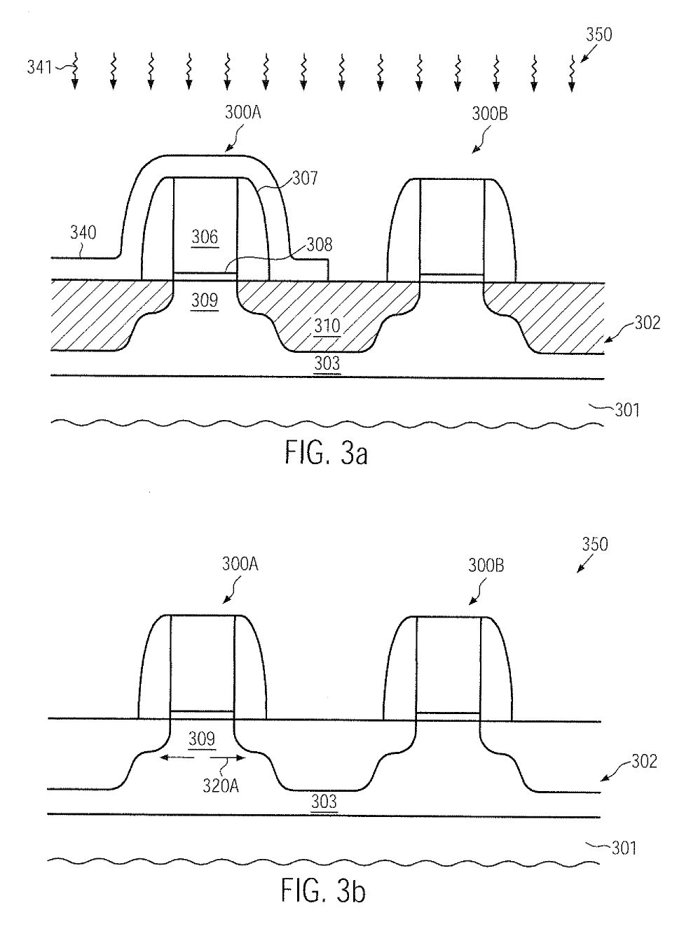

FIG. 2a schematically illustrates a top view of a semiconductor device 250 which, in one illustrative embodiment, may represent a portion of an integrated circuit in which, at least in some device areas, transistor elements of the same conductivity type are to be formed in and above a single active semiconductor region. In one embodiment, the semiconductor device 250 may represent a portion of a static RAM cell having an electrical configuration as is also explained with reference to FIG. 1a. The semiconductor device 250 may comprise a substrate (not shown) above which may be formed a semiconductor layer (not shown) in which an isolation structure 204, which may be comprised of any appropriate insulating material, such as silicon dioxide, silicon nitride and the like, may define an active semiconductor region 203. As previously indicated, an active region is to be understood as a continuous semiconductor region without intermediate isolation structures, in and above which two or more transistor elements of the same conductivity type are to be formed. As shown, the active region 203 may comprise components of a first transistor 200A and a second transistor 200B, which may represent transistors of the same conductivity type, such as N-channel transistors or P-channel transistors, which, however, may have a different drive current capability, as required by the overall configuration of the device 250. In one illustrative embodiment, the first transistor 200A may represent a pull-down transistor of a static RAM cell, while the second transistor 200B may represent a pass transistor that is connected to the pull-down transistor 200A via the common active region 203. In one illustrative embodiment, the active region 203 may have a width dimension 203A that is substantially identical for the first transistor 200A and the second transistor 200B. That is, the width 203A may, except for any process variations, be the same for the first and second transistors 200A, 200B. In other illustrative embodiments, the width 203A may be different for the transistors 200A, 200B, however, with a less pronounced degree, as is for instance illustrated in FIG. 1b of a conventional static RAM cell, in which a pronounced difference in the drive current capability may be required. However, according to the principles disclosed herein, a respective variation of the transistor width 203A, if desired, may be provided with a less pronounced degree since a significant difference in drive current capability between the transistors 200A, 200B may be obtained by creating different strain levels in the region 203, as previously explained, so that a less sophisticated geometry of the region 203, in combination with efficient strain engineering techniques, may provide the desired different drive current capabilities. In the illustrative embodiment shown in FIG. 2a, the portion of the region 203 accommodating the first and second transistors 200A, 200B may have a substantially rectangular configuration, thereby providing very efficient process conditions during lithography, etch processes and the like, so that enhanced overall process uniformity may be accomplished, thereby reducing yield losses even if semiconductor devices of critical dimensions of approximately 50 nm and less may be considered.

In the embodiment shown, the transistors 200A, 200B may comprise a gate electrode 206 having, in some illustrative embodiments, a length 206L of 50 nm or less, wherein, for instance, the length 206L may be substantially identical except for process variations for the transistors 200A, 200B. Furthermore, a portion of the active region 203 corresponding to the first transistor 200A may have a first internal strain level, indicated by 220A, while a portion of the region 203 corresponding to the second transistor 200B may have a second internal strain level 200B, which differs from the level 220A in at least one type of strain and magnitude. That is, the strain levels 220A, 220B may represent the same type of strain, such as tensile strain or compressive strain, while the amount thereof may be different, while, in other cases, the type of strain, i.e., compressive strain or tensile strain, may be different in the first and second transistors 200A, 200B while, if desired, the amount of the corresponding different types of strain may also differ. Consequently, as previously explained, the different strain levels 220A, 220B locally provided in the active region 203 so as to correspond to the first and second transistors 200A, 200B, respectively, may create different charge carrier mobility in the channel regions, which may thus result in different drive current capabilities for the transistors 200A, 200B.

FIG. 2b schematically illustrates a cross-sectional view of the device 250 along the line IIb of FIG. 2a. As illustrated, the device 250 may comprise a substrate 201 above which may be formed a semiconductor layer 202, in which is defined the active region 203. The substrate 201, in combination with the semiconductor layer 202, may define a bulk configuration, i.e., the semiconductor layer 202 may represent an upper portion of a crystalline semiconductor material of the substrate 201, or may define a silicon-on-insulator (SOI) configuration, when a buried insulating layer (not shown) may be provided between the substrate 201 and the semiconductor layer 202. It should be appreciated that a bulk configuration and an SOI configuration may commonly be provided in the device 250 at different areas, if considered appropriate. For example, device areas including speed critical signal paths may be provided as an SOI configuration, while other areas may be provided in the form of a bulk configuration, if considered appropriate. Furthermore, in the manufacturing stage shown, the transistors 200A, 200B may comprise the gate electrodes 206, which are separated from channel regions 209 by gate insulation layers 208. Furthermore, a spacer structure 207 may be formed on sidewalls of the gate electrodes 206. Moreover, drain and source regions 210 having any appropriate lateral and vertical dopant profile may be formed in the common active region 203, which may have substantially the same configuration for the first and second transistors 200A, 200B, since the drain and source regions 210 may be formed in a common manufacturing sequence. Additionally, a strain level in the channel region 209 of the first transistor 200A, indicated by 220A as previously explained, may be different from the strain level 220B in the channel region of the second transistor 200B. In the embodiment shown, it may be assumed that the first and second transistors 200A, 200B represent N-channel transistors, wherein the drive current capability of the first transistor 200A may have to be adjusted to a higher value compared to the second transistor 200B. In this case, the first strain level 220A may represent, for instance, a tensile strain component, which may enhance the electron mobility and thus the drive current capability of the transistor 200A. On the other hand, the strain component 220B may represent a substantially neutral strain level or a tensile strain level with a reduced amount compared to the level 220A, thereby providing a less pronounced charge carrier mobility and thus drive current capability. In still other cases, as will be described later on in more detail, other strain conditions may be established to provide a higher drive current capability in the first transistor 200A compared to the second transistor 200B.

The semiconductor device 250 as shown in FIG. 2b may be formed on the basis of the following processes. First, the isolation structure 204 may be formed on the basis of photolithography, etch, deposition and planarization techniques, similarly as described above with reference to the device 150, wherein, however, if desired, a geometric configuration of the active region 203 and thus the isolation structure 204 with reduced complexity may be used compared to the conventional device so that process-related non-uniformities may be suppressed. Thereafter, an appropriate basic dopant concentration may be established, as previously explained, and the gate insulation layers 208 and the gate electrodes 206 may be formed in accordance with well-established process techniques. Thereafter, the drain and source regions 210 may be formed by ion implantation processes, as previously described, and anneal cycles may be performed so as to re-crystallize implantation-induced damage and activate dopant atoms. As will be described later on, in some illustrative embodiments, selective stress memorization techniques may be applied so as to locally provide the different strain levels 220A, 220B in the active region 203. In other cases, the manufacturing sequence may be continued, as previously explained, for instance by forming respective metal silicide regions 211, wherein, due to the geometric configuration of the active region 203 of reduced complexity, the probability of creating process-induced irregularities may be reduced, thereby contributing to enhanced production yield. Next, a dielectric layer 230 may be formed, for instance in the form of a silicon nitride material or any other appropriate dielectric material, which may be used as an efficient etch stop material during the patterning of a further interlayer dielectric material, such as a silicon dioxide material, which may be formed on the dielectric layer 230.

Consequently, the drive current capabilities of the transistors 200A, 200B may be appropriately adjusted on the basis of the different strain levels 220A, 220B which, in some illustrative embodiments, may, possibly in combination with any strain-inducing mechanisms provided during the previous processing, also be accompanied by a respectively patterned internal stress level of the dielectric layer 230.

FIG. 2c schematically illustrates the semiconductor device 250 according to illustrative embodiments in which the different strain levels 220A, 220B may be provided by the dielectric layer 230. For this purpose, the layer 230 may be deposited with a desired high internal stress level during a deposition process 231 after completing the basic transistor structures 200A, 200B, as previously described. The deposition process 231 may represent a plasma assisted chemical vapor deposition (CVD) for providing a silicon nitride material, a nitrogen-containing silicon carbide material, a silicon dioxide material and the like, depending on the overall process strategy. In one illustrative embodiment, the dielectric layer 230 may be deposited in the form of a silicon nitride material having a high internal tensile stress level, which may be accomplished on the basis of well-established deposition recipes, in which process parameters, in particular the degree of ion bombardment in combination with process gas flow rates, pressure and temperature, may be controlled to obtain the desired high tensile stress component. The dielectric material 230 may be deposited with a thickness in accordance with overall device requirements, wherein, for sophisticated devices and surface topographies, a layer thickness of approximately 30-100 nm may be used.

FIG. 2d schematically illustrates the semiconductor device 250 in an advanced manufacturing stage in which an etch mask 232 may be provided to cover at least the first transistor 200A, i.e., a portion of the active region 203 associated with the gate electrode 206 of the transistor 200A, wherein the mask 232 may cover portions of the drain and source regions of the transistor 200A that are substantially equal in size at both sides of the gate electrode 206, while, in other cases, any desired “boundary” may be created by the mask 232 between the transistors 200A, 200B. On the basis of the etch mask 232, the device 250 may be exposed to an etch ambient 233 for selectively removing an exposed portion of the layer 230, which may be accomplished by providing an etch stop layer (not shown) prior to the deposition of the dielectric layer 230. For example, in combination with a silicon nitride material, silicon dioxide may act as an efficient etch stop material and thus well-established selective etch recipes may be used for removing the exposed portion of the layer 230 without creating undue damage in the transistor 200B. In other cases, the metal silicide regions 211 may act as an etch stop or etch control material, if desired.

FIG. 2e schematically illustrates the semiconductor device 250 after the selective removal of the exposed portion of the layer 230 and the removal of the etch mask 232. Furthermore, a further dielectric layer 230B may be formed on the remaining layer 230 and above the second transistor 200B. The second layer 230B may exhibit any appropriate internal stress level so as to establish, in combination with the layer 230, the different strain levels 220A, 220B, as previously explained. For example, if the layer 230 has been formed with a high degree of tensile stress level so as to enhance performance of the first transistor 200A, the layer 230B may be provided with a significantly reduced tensile stress or as a substantially stress-neutral material, thereby creating only a significantly reduced strain level in the transistor 200B. In other illustrative embodiments, the layer 230B may be provided with a different type of internal stress, for instance a compressive stress level, thereby creating a respective compressive strain in the transistor 200B, which may reduce charge carrier mobility in the case of an N-channel transistor, thereby also reducing the respective drive current capability. In this case, a pronounced difference in the strain levels 220A, 220B may be accomplished. As previously explained, silicon nitride material may be provided in the form of a compressive material, a tensile material or a substantially stress-neutral material, depending on the deposition parameter values used.

FIG. 2f schematically illustrates the semiconductor device 250 in a further advanced manufacturing stage according to illustrative embodiments in which a portion of the layer 230B is moved from above the first transistor 200A. To this end, an appropriate etch mask may be formed to expose the portion of the layer 230B above the first transistor 200A and applying an appropriate etch recipe wherein, if desired, an etch stop layer (not shown) may be formed prior to the deposition of the layer 230B at any appropriate manufacturing stage, for instance after the deposition of the layer 230 and prior to the patterning thereof during the etch process 233 (FIG. 2d).

Thereafter, the further processing may be continued by depositing an interlayer dielectric material, as previously explained, and patterning the same, wherein the layers 230, 230B may be used as efficient etch stop materials. Consequently, an appropriate “patterning” of the drive current capability of the transistors 200A, 200B may be accomplished on the basis of the dielectric material 230, 230B, without requiring sophisticated geometric shapes of the active region 203. It should be appreciated that the ratio of the drive current capabilities of the transistors 200A, 200B may be adjusted on the basis of a plurality of variations with respect to adjusting the internal stress levels of the layers 230, 230B, as will be described with reference to FIGS. 2g-2i.

FIG. 2g schematically illustrates a top view of the device 250, in which the first transistor 200A may be covered by the layer 230 having a moderately high tensile stress level, as previously explained. On the other hand, the layer 230B may have a substantially neutral internal stress level, thereby providing an increased drive current capability of the transistor 200A compared to the transistor 200B, when both transistors represent N-channel transistors.

FIG. 2h schematically illustrates the semiconductor device 250, wherein the layer 230 may represent a substantially neutral dielectric material while the layer 230B may be provided in the form of a compressive dielectric material. Hence, also in this case, the resulting drive current capability of the first transistor 200A may be higher than the drive current capability of the second transistor 200B when representing N-channel transistors. It should be appreciated that a neutral internal stress level is to be understood as a stress level which is obtained on the basis of deposition parameters which may result in a significantly reduced amount of stress compared to the tensile stress of the layer 230 in FIG. 2g and to the compressive stress of the layer 230B in FIG. 2h. That is, an internal stress level of several tenths of Mpa (Mega Pascal) may be considered as a substantially neutral internal stress level.

FIG. 2i schematically illustrates the device 250 according to a still further illustrative embodiment in which a high difference between the drive current capabilities may be obtained by providing the layer 230 with a high tensile stress level, while the layer 230B may have a compressive internal stress level. Hence, drive current capability of the transistor 200A may be significantly higher compared to the transistor 200B when both transistors represent N-channel transistors.

It should be appreciated that a corresponding adjustment of the drive current capabilities within the active region 203 may also be accomplished for P-channel transistors, wherein it is to be appreciated that a compressive strain enhances the drive current capability of a P-channel transistor while a tensile strain may reduce the corresponding drive current capability.

FIG. 2j schematically illustrates the semiconductor device 250 according to still further illustrative embodiments in which the different strain levels 220A, 220B may be obtained by selectively modifying the internal stress level of the layer 230 after the deposition thereof. For instance, the layer 230 may be deposited with a high compressive stress level and thereafter an implantation mask 235 may be formed to cover the second transistor 200B, in which a reduced drive current capability is desired. Furthermore, an implantation process 234 may be performed to selectively relax the compressive strain in the exposed portion of the layer 230, thereby also reducing the compressive strain component in the first transistor 200A, which may thus exhibit an increased drive current capability compared to the transistor 200B. The implantation process 234 may be performed on the basis of an appropriate species, such as xenon and the like, wherein respective process parameters, such as the implantation energy, may be determined on the basis of simulation, experiment and the like. Using a heavy implantation species, such as xenon, may enable a desired significant relaxation of the internal stress level at a moderately low implantation dose. It should be appreciated, however, that any other implantation species may be used, wherein the corresponding appropriate process parameters, such as energy and dose, may be efficiently determined by test runs, simulation and the like.

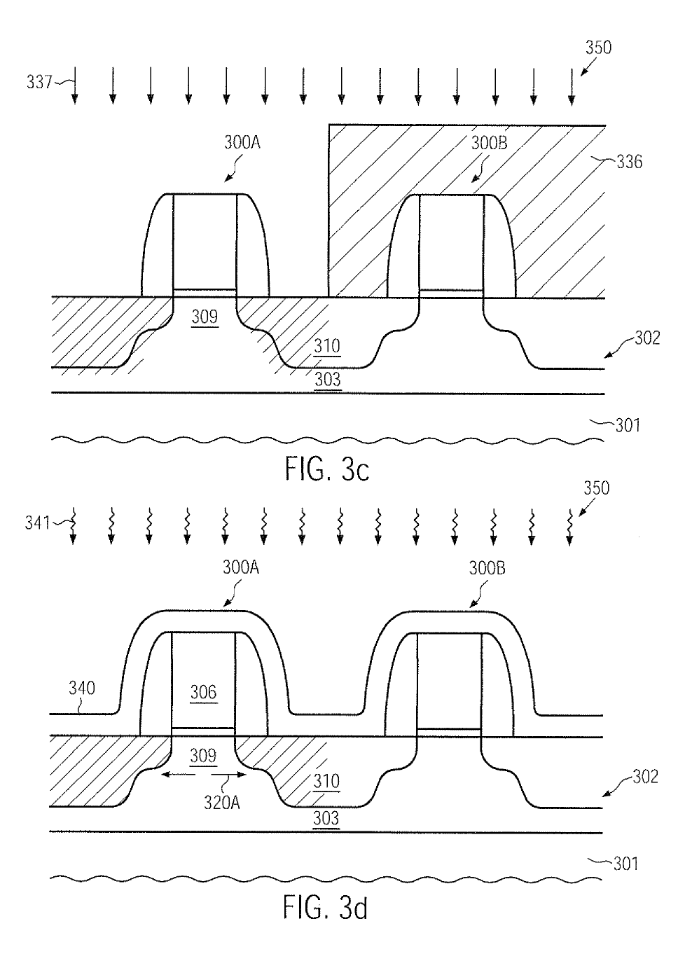

With reference to FIGS. 3a-3d, further illustrative embodiments will now be described in which, in addition to the strain-inducing mechanisms described above or alternatively to these approaches, different strain levels may be established by a stress memorization technique.

FIG. 3a schematically illustrates a semiconductor device 350 comprising a substrate 301 above which is formed a semiconductor layer 302, comprising an active region 303 in and above which a first transistor 300A and a second transistor 300B may be formed. For example, the transistors 300A, 300B may represent a pull-down transistor and a pass transistor, respectively, of a static RAM cell. In the manufacturing stage shown, the first and second transistors 300A, 300B may each comprise a gate electrode 306 formed on a gate insulation layer 308, which separates the gate electrode 306 from a channel region 309. Furthermore, a sidewall spacer structure 307 may be formed on sidewalls of the gate electrodes 306. With respect to components described so far, the same criteria apply as previously explained with reference to the semiconductor device 250. Furthermore, in the manufacturing stage shown, drain and source regions 310 may be defined in the active region 303, wherein, however, the drain and source regions 310, at least significant portions thereof, may still be in a highly damaged state or may be in a substantially amorphous state, for instance due to a preceding ion implantation process, which may include, if required, an amorphization implantation process on the basis of an appropriate species, such as xenon, silicon and the like. Furthermore, a cap layer 340 may be selectively formed above the first transistor 300A, wherein the cap layer 340 may be comprised of a rigid material, such as silicon nitride. The layer 340 may be formed by well-established deposition techniques, such as plasma enhanced CVD, followed by a lithography step for providing an etch mask and selectively removing the cap layer 340 on the basis of well-established etch recipes. Also, an etch stop liner (not shown) may be provided prior to the deposition of the layer 340, wherein the etch stop liner may be used for controlling the selective etch process. Next, the device 350 may be exposed to an anneal process 341, which may be performed on the basis of appropriate process parameters, such as temperature and duration, in order to activate dopants in the drain and source regions 310 and also re-crystallize the damaged portions thereof. During the anneal process 341, the cap layer 340 may substantially suppress a reduction of volume of the underlying semiconductor material upon re-crystallizing material, thereby creating a strained state of drain and source portions of the first transistor 300A. Without intending to restrict the present disclosure to the following explanation, it is believed that, during the preceding implantation processes, the substantially crystallize lattice structure may be destroyed or at least significantly damaged, thereby creating an increase of volume since, typically, a substantially amorphous material may occupy an increased volume. During the anneal process 341, the stiffness of the cap layer 340, in combination with the strong adhesion of the cap layer 340 to the semiconductor material, may substantially suppress a reduction of volume upon re-crystallization of the drain and source areas, which may result in a strained re-growth of the previously damaged or substantially amorphous portions. Due to the strained re-growth and connection to the remaining crystalline portions of the active region 303, which may act as a crystallization template, the strained state may be substantially maintained even if the cap layer 340 may be removed. Consequently, the strained drain and source areas may also induce a respective tensile strain component in the channel region 309.

FIG. 3b schematically illustrates the device 350 after the anneal process 341 and the removal of the cap layer 340, which may be accomplished on the basis of an etch stop liner, as previously explained. Hence, a tensile strain component 320A may be selectively obtained in the channel region 309 of the first transistor 300A, thereby providing the desired difference in drive current capability between a first and second transistor 300A, 300B.

FIG. 3c schematically illustrates the device 350 according to still further illustrative embodiments in which a selective stress memorization technique may be applied, wherein the drain and source regions 310 may be selectively brought into a highly damaged state or a substantially amorphous state in the first transistor 300A, which may be accomplished on the basis of an implantation mask 336, which covers the second transistor 300B while exposing the first transistor 300A to an ion implantation process 337 for substantially amorphizing portions of the drain and source areas in the first transistor 300A. Prior to performing the ion implantation process 337, the drain and source regions 310 may have been formed in the first and second transistors 300A, 300B in a common process sequence, which may include appropriate anneal processes so as to provide a substantially crystalline state of the drain and source regions 310. Thereafter, the implantation mask 336 may be formed and the drain and source areas 310 of the first transistor 300A may be selectively damaged or amorphized during the process 337 so as to provide the preconditions for a strained re-growth of these areas in the first transistor 300A.

FIG. 3d schematically illustrates the device 350 in a further advanced manufacturing stage in which a cap layer 340 is formed above the first and second transistors 300A, 300B and wherein the anneal process 341 may be performed without patterning the layer 340. Due to the substantially crystalline state of the drain and source regions 310 in the second transistor 300B, a strain level therein may not be significantly increased while, on the other hand, the corresponding re-crystallization may result in a highly strained state of the drain and source regions, as previously explained. Hence, also in this case, a selective tensile strain component may be obtained in the first transistor 300A, thereby providing the difference in drive current capability.

It should be appreciated that the embodiments described with reference to FIGS. 3a-3d may also be efficiently combined with the strain-inducing mechanisms as described with reference to the device 250, since the stress memorization techniques may be applied prior to forming the highly stressed dielectric materials 230, 230B. Consequently an even more pronounced difference in drive current capability may be accomplished by applying the stress memorization techniques as described with reference to the device 350 and subsequently forming the dielectric layers 230, 230B with an appropriate internal stress level.

As a result, the present disclosure provides methods and semiconductor devices in which the drive current capability of transistors formed in and above the same active region may be adjusted on the basis of locally applied strain-inducing mechanisms, such as the provision of dielectric material with appropriately selected internal stress levels and stress memorization techniques, so that an overall transistor configuration of reduced complexity may be obtained while nevertheless providing a significant difference in drive current capability. In some illustrative embodiments, a pull-down transistor and a pass transistor of a static RAM cell may be formed in a common active region without requiring a pronounced variation of the transistor width of these transistor elements, since the different drive current capabilities may be efficiently adjusted on the basis of the selective strain-inducing mechanisms. Thus, the geometric configuration of the active region of reduced complexity may result in a reduction of yield losses for sophisticated integrated circuits, in which the channel length may be 50 nm and significantly less. For example, a substantially rectangular configuration may be used for the common active semiconductor region, thereby providing enhanced conditions during lithography and etch processes. Furthermore, in some circuit configurations, a plurality of pull-down transistors and pass transistors may be formed in a common active region of reduced complexity wherein the corresponding drive current capability adaptation may be accomplished on the basis of the selective strain-inducing mechanisms as described above.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first transistor of a memory cell above a substrate of a semiconductor device, said first transistor having a first conductivity type and a first transistor width;
forming a second transistor of said memory cell, said second transistor having said first conductivity type and said first transistor width; and
adjusting a ratio of drive current capabilities of said first and second transistors by inducing different strain levels in channel regions of said first and second transistors.

2. The method of claim 1, wherein adjusting a ratio of drive current capabilities of said first and second transistors comprises creating a first type of strain in a first channel region of said first transistor, said first type of strain increasing charge carrier mobility in said first channel region.

3. The method of claim 2, further comprising inducing a reduced amount of said first type of strain in a second channel region of said second transistor.

4. The method of claim 3, wherein said reduced amount of said first type of strain corresponds to a substantially neutral strain level.

5. The method of claim 2, further comprising inducing a second type of strain in a second channel region of said second transistor, said second type of strain reducing charge carrier mobility in said second channel region.

6. The method of claim 1, wherein adjusting a ratio of drive current capabilities comprises inducing a second type of strain in a second channel region of said second transistor, said second type of strain reducing charge carrier mobility in said second channel region.

7. The method of claim 6, further comprising inducing a reduced amount of strain in a first channel region of said first transistor.

8. The method of claim 7, wherein said reduced amount of strain corresponds to a substantially neutral strain level in said first channel region.

9. The method of claim 1, wherein inducing different strain levels in said channel regions comprises forming a first dielectric layer above said first transistor and forming a second dielectric layer above said second transistor, said first and second dielectric layers having a different internal stress level.

10. The method of claim 9, wherein forming said first and second dielectric layers comprises forming said first dielectric layer above said first and second transistors so as to have a specific internal stress level and selectively reduce said specific internal stress level above said second transistor.

11. The method of claim 9, wherein forming said first and second dielectric layers comprises forming said first dielectric layer above said first and second transistors so as to have a specific internal stress level, selectively removing said first dielectric layer from above one of said first and second transistors and selectively forming said second dielectric layer above said one of said first and second transistors.

12. The method of claim 1, wherein inducing different strain levels in channel regions of said first and second transistors comprises re-crystallizing drain and source regions of said first transistor in the presence of a cap layer so as to form said drain and source regions in a strained state, while substantially avoiding a strained re-crystallization of drain and source regions of said second transistor.

13. The method of claim 12, wherein re-crystallizing said drain and source regions of said first transistor in the presence of said cap layer comprises forming said cap layer above said first and second transistors and selectively removing said cap layer from above said second transistor prior to annealing said first and second transistors.

14. The method of claim 12, wherein re-crystallizing said drain and source regions of said first transistor in the presence of said cap layer comprises establishing a substantially crystalline state in drain and source areas of said second transistor while creating a substantially amorphous state in said drain and source regions of said first transistor, forming said cap layer above said first and second transistors and annealing said first and second transistors when covered by said cap layer.

15. A method, comprising:
forming a first transistor in and above an active semiconductor region;
forming a second transistor in and above said active semiconductor region;
inducing a first strain level in a channel region of said first transistor; and
inducing a second strain level in a channel region of said second transistor, said second strain level differing from said first strain level in at least one of type of strain and magnitude.

16. The method of claim 15, wherein inducing said first and second strain levels comprises forming a first dielectric layer above said first transistor and forming a second dielectric layer above said second transistor, said first and second transistors having different internal stress levels.

17. The method of claim 15, wherein inducing said first and second strain levels comprises forming drain and source regions of one of said first and second transistors in a strained state during an anneal process.

18. The method of claim 15, wherein said active region represents a device area of a memory area of a semiconductor device.

19. The method of claim 16, wherein forming said first and second dielectric layers comprises forming said first dielectric layer above said first and second transistors, selectively remove said first dielectric layer from above said second transistor and selectively forming said second dielectric layer above said second transistor.

20. The method of claim 16, wherein forming said first and second dielectric layers comprises forming said first dielectric layer above said first and second transistors and selectively relaxing a stress level of said first dielectric layer above said second transistor.

21. A semiconductor device, comprising:
an active semiconductor region formed above a substrate;
a first transistor formed in and above said active semiconductor region, said first transistor comprising a first channel region having a first strain level; and
a second transistor formed in and above said active semiconductor region, said second transistor comprising a second channel region having a second strain level that differs from said first strain level.

22. The semiconductor device of claim 21, wherein a transistor width of said first and second transistors is substantially identical.

23. The semiconductor device of claim 22, further comprising a first dielectric layer formed above said first transistor and a second dielectric layer formed above said second transistor, wherein said first and second dielectric layers have a different internal stress level for inducing said first and second strain levels.

24. The semiconductor device of claim 20, wherein said first and second transistors represent transistors of a memory cell, and wherein said first transistor has first drive current capability that is higher than a second drive current capability of said second transistor.

25. The semiconductor device of claim 20, wherein said first strain level is one of a tensile strain level and a compressive strain level and said second strain level is a substantially neutral strain level.

26. The semiconductor device of claim 24, wherein said first strain level is a tensile strain level and said second strain level is a compressive strain level.

27. The semiconductor device of claim 24, wherein said first strain level is a substantially neutral strain level and said second strain level is a compressive strain level.
